(19) United States
(12) Patent Application Publication
(10) Pub. No.: US 2012/0104253 A1
(43) Pub. Date: May 3, 2012

(54) CHARGED PARTICLE BEAM MICROSCOPE AND MEASURING METHOD USING SAME

(75) Inventors: Ruriko Tsuneta, Fuchu (JP); Hideki Kikuchi, Hitachinaka (JP); Takafumi Yotsuji, Hitachinaka (JP)

(73) Assignee: HITACHI HIGH-TECHNOLOGIES CORPORATION, MINATO-KU, TOKYO (JP)

(21) Appl. No.: 13/383,259

(22) PCT Filed: Jun. 1, 2010
(86) PCT No.: PCT/JP2010/003654

§ 371 Date: Jan. 10, 2012

(30) Foreign Application Priority Data
Jul. 16, 2009 (JP) 2009-167711

(51) Int. Cl. H01J 37/28; G01N 23/00

(52) U.S. Cl. 250/307; 250/310

(57) ABSTRACT

A charged particle beam device is equipped with a function of: obtaining an approximation function of a sample drift from a visual field shift amount among plural images (S1); capturing a save image while correcting the drift on the basis of the approximation function (S2); and creating from the save image a target image in which the effect of the sample drift is reduced (S3). This makes it possible to smooth the random errors in the visual field shift measurements by approximating the sample drift to the function and also to predict the sample drift changing over time. Therefore, it is possible to provide a charged particle beam device in which the effect of the sample drift is very limited even in a high magnification and also provide a measuring method using the charged particle beam device.

### TECHNICAL FIELD

The present invention relates to a charged particle beam microscope such as a scanning electron microscope or an ion microscope and a measuring method using the same.

For the development of a semiconductor device and nanomaterials, it is necessary to analyze a structure of a specimen using a charged particle beam microscope such as a scanning electron microscope (SEM), a scanning transmission electron microscope (STEM), a transmission electron microscope (TEM) that is capable of examining the structure of the specimen with a spatial resolution in the unit of a nanometer.

The charged particle beam apparatus is disclosed in, for example, Patent Literatures 1 and 2.

### CITATION LIST

### Patent Literatures

Patent Literature 1: JP-B No. 4065847
Patent Literature 2: JP-A No. H05-290787

### SUMMARY OF INVENTION

### Technical Problem

Accompanied by the miniaturization and complication of the examination object, the examining device becomes highly precise. One of the obstructive factors of high precision is sample drift. If there is sample drift, the captured image is blurred or distorted. The states are shown in FIGS. 2A to 2C.

FIG. 2A shows an original image. A STEM scans a sample using a finely focused electron beam, detects the electron beam that passes through the specimen and synchronizes the electron beam with a scanning signal to form an image. A SEM detects a secondary electron or a reflective electron to form an image.

The blurring or distortion of the image depends on the image capturing method. There are a fast scanning method that a beam is scanned at a high speed to form plural images, and then the images are integrated to capture a temporary image and a slow scanning method that a temporary image is captured by one low speed scanning. According to the fast scanning method, a sample drift causes a image drift (visual field shift) generated between the frames. When the visual field shift is integrated, the temporary image is blurred in the drift direction (see FIG. 2B).

Meanwhile, according to the slow scanning method, the sample drift causes an image distortion in the drift direction (see FIG. 2C). According to a TEM that an electronic beam is irradiated in parallel to the specimen and the electronic beam that transmits the specimen is detected by a camera to form an image, the sample drift acts as an image blurring.

As a result of researching a technology of reducing the influence of the sample drift, the following technologies are obtained. In Patent Literature 1, a drift compensation technology in the SEM is described. According to a first embodiment thereof, if an objective image is captured by a fast scanning method, plural sheets of fast scanned frame integration images are captured, the frame integration images are integrated while correcting the visual field shift between the images so that the final image with reduced drift influence can be obtained.

According to a second embodiment thereof, two sheets of fast scanned frame integration images are captured, and the visual field shift between the both images is calculated, plural sheets of fast scanned frame integration images are captured while moving the visual field using an image shift deflector (hereinafter, abbreviated as an image shift) or a specimen stage in a direction of cancelling the visual field shift. Further, the final image is obtained by measuring the visual field shift between the frame integration images and accumulating the visual field shift while correcting the visual field shift.

According to a third embodiment thereof, in the case of capturing the objective image by a slow scanning method, before, after, or before and after capturing the temporary image, two sheets of fast scanned frame integration images are captured, the amount of drift between the images is calculated, and a modified amount of the temporary image in a perpendicular direction and a horizontal direction is calculated based on the drift amount. Therefore, a captured temporary image F0 is modified to make a new objective image F0′.

Further, the following technology is disclosed in Patent Literature 2. A first scanning electronic microscope includes means for detecting the visual field shift amount by matching image data in a small region in or outside an observation area with image data in the small region obtained by scanning after a predetermined period of time and means for correcting a scanning position of an electronic beam with respect to a specimen so as to compensate the detected visual field shift.

A second scanning electronic microscope includes means for detecting the drift amount of an image by matching image data in a small region inside or outside an observation area with image data in the small region obtained by scanning after a predetermined period of time and means for integrating the images by shifting the pixels so as to compensate the detected visual field shift.

A third scanning electronic microscope includes means for storing a line scanned signal obtained from a sample by subjecting one or plural line scanning of electronic beams on the sample and means for obtaining a correlation between adjacent signals using a signal obtained by the line scanning as a unit and storing an image in an image memory per the unit by shifting the pixels so as to maximize the correlation by the correlation process.

However, even in the charged particle beam apparatus with the configuration described in the above Patent Literatures, for example, if a diameter of the visual field is set to a high magnification of 250 nm×250 nm, the drift compensation is insufficient.

The object of the present invention is to provide a charged particle beam microscope and a measuring method using the same that that is not influenced or little influenced by the sample drift even in high efficiency and a measurement method using the same.

### Solution to Problem

To achieve the above objects, an embodiment is a charged particle beam microscope, including: a charged particle generating source; a charged particle generating source control circuit that controls the charged particle generating source; a specimen stage that mounts a specimen onto which the charged particle discharged from the charged particle generating source is irradiated, a specimen stage control circuit that controls the specimen stage; a detector that detects the charged particles from the specimen; a detector control circuit that controls the detector; a computer that controls the control circuits; and a display part that is connected to the computer. The computer includes: a recording part that records plural images created using charged particles from a predetermined pattern formed on the specimen at different timings; a calculation part that calculates the visual field shift amount between the plural images using the predetermined pattern in the image; and an analysis unit that calculates an approximation function that is used for the compensation of the visual field shift caused by the sample drift from the visual field shift amount.

Further, another embodiment is a method of measuring a predetermined pattern from an image obtained by irradiating a charged particle beam onto the predetermined pattern of a specimen using a charged particle beam microscope, the method including: a first step of capturing plural images including the predetermined pattern at different timings; a second step of obtaining the visual field shift amount between the plural images; a third step of obtaining an approximation function that is used for compensating the visual field shift caused by the sample drift from the visual field shift amount between the plural images; and a fourth step of offsetting the visual field shift based on the approximation function.

In addition, yet another embodiment is a charged particle beam microscope, including: a charged particle generating source; a charged particle generating source control circuit that controls the charged particle generating source; a specimen stage that mounts a specimen onto which the charged particle discharged from the charged particle generating source is irradiated, a specimen stage control circuit that controls the specimen stage; a detector that detects the charged particles from the specimen; a detector control circuit that controls the detector; a computer that controls the control circuits; and a display part that is connected to the computer. The display unit carries out: a compensation condition setup that compensates a visual field shift in a captured image obtained based on the charged particles from the specimen; an approximation function setup that approximates a locus of a sample drift of the specimen used for compensating the visual field shift; and a capture completion condition setup of the specimen.

### Advantageous Effects of Invention

It is possible to provide a charged particle beam microscope and a measuring method using the same that that is not influenced or little influenced by the sample drift even in high efficiency and a measurement method using the same.

### BRIEF DESCRIPTION OF DRAWINGS

FIG. 1A shows an example of a display image of a sample drift compensation system in slow scan capturing of an STEM/SEM according to a first embodiment.

FIG. 1B shows an example of a display image of a sample drift compensation system in slow scan capturing of the STEM/SEM according to the first embodiment.

FIG. 1C shows an example of a display image of a sample drift compensation system in slow scan capturing of an STEM/SEM according to the first embodiment.

FIG. 2A shows an original image for explaining the image blurring and distortion caused by the sample drift.

FIG. 2B shows an image blurred by the sample drift for explaining the image blurring and distortion caused by the sample drift.

FIG. 2C shows an image distorted by the sample drift for explaining the image blurring and distortion caused by the sample drift.

FIG. 3 is a basic flow chart of sample drift compensation of a charged particle beam microscope according to an embodiment.

FIG. 4 is a flow chart of sample drift compensation in slow scan capturing of the charged particle beam microscope according to the embodiment.

FIG. 5 is an explanatory view showing the difference between an approximate function obtained from a locus of sample drift before capture of the charged particle beam microscope and an approximate function obtained from a locus of sample drift before and after capturing the charged particle beam microscope according to the embodiment.

FIG. 6 is an explanatory view showing a method for creating a final image from a temporary image captured by slow scan of the STEM/SEM according to the first embodiment.

FIG. 7 is an explanatory view showing a method for creating a final image from a temporary image captured by slow scan of the charged particle beam microscope according to the embodiment.

FIG. 8 is a flow chart of sample drift compensation in fast scan capturing of the STEM/SEM according to a second embodiment.

FIG. 9A is an explanatory view showing a method for creating a final image from a temporary image captured by fast scan of the charged particle beam microscope according to the embodiment.

FIG. 9B is an explanatory view showing a method for creating a final image from a temporary image captured by fast scan of the charged particle beam microscope according to the embodiment.

FIG. 10 is a schematic view showing a basic configuration of the STEM/SEM according to the first embodiment.

FIG. 11A shows an example of a display screen of a sample drift compensation system in fast scan capturing of an STEM/SEM according to a second embodiment.

FIG. 11B shows an example of a display screen of a sample drift compensation system in fast scan capturing of the STEM/SEM according to the second embodiment.

FIG. 12 is a flow chart of sample drift compensation in line divisional capturing of slow scan of an STEM/SEM according to a third embodiment.

FIG. 13A shows an example of a display screen of a sample drift compensation system in line divisional capturing of slow scan of an STEM/SEM according to the third embodiment.

FIG. 13B shows an example of a display screen of a sample drift compensation system in line divisional capturing of slow scan of an STEM/SEM according to the third embodiment.

FIG. 14 is a schematic view showing a basic configuration of a scanning electronic microscope according to a fourth embodiment.

FIG. 15 is a schematic view showing a basic configuration of a transmission electronic microscope according to a fifth embodiment.

FIG. 16 shows an example of a time variation of a sample drift speed after stopping a specimen stage in the specimen stage of an STEM/SEM.

### DESCRIPTION OF EMBODIMENTS

The inventors studied the related arts and found out that the related arts compensated the image drift (visual field shift) by converting the amount of visual field shift obtained from an image for measuring the visual field shift into a compensation amount or a sample drift speed, so that high precision compensation could not be performed. Specifically, the measuring error of the visual field shift could not be ignored.

If a blurred image is used, the measuring error of the visual field shift is increased. If the capturing magnification is increased, the size of one pixel becomes accordingly small, but there is an upper limit for the resolution of STEM. Therefore, if the pixel size is smaller than the resolution, the image is blurred.

For example, the resolution when observing a specimen of several 100 nm thickness using a general-purpose STEM is approximately 1 nm. In a case where a region of a visual field diameter of 250 nm×250 nm is captured with 500×500 pixels, a pixel size is 0.5 nm. Therefore, it is assumed that the visual field shift amount of an image captured under this condition may have a measuring error of approximately ±0.5 pixel. In the meantime, the sample drift amount under the image capture that is assumed by the general-purpose STEM is several nm to several tens nm. The measuring error of 0.5 nm is 50% with respect to 1 nm, and 5% with respect to 10 nm, which cannot be ignored.

If the visual field shift amount is converted into a direct compensation amount, the measuring error becomes a compensation error, which degrades the final image. The image blurring or distortion due to the sample drift becomes obvious at the time of high magnification capturing, and the sample drift compensation is required at the time of high magnification capturing. However, the related arts did not consider the increase of the measuring error of visual field shift that became obvious at the time of high magnification capturing.

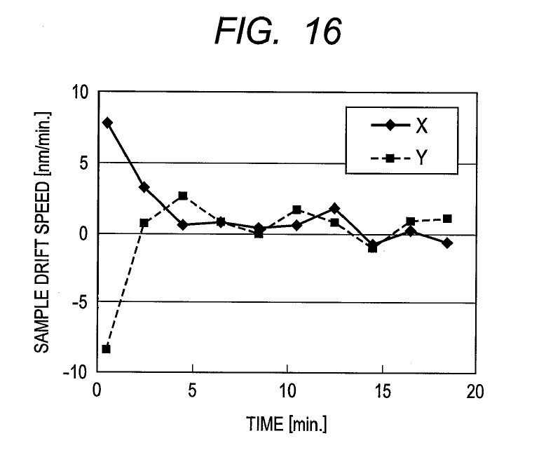

Furthermore, in the related arts, the high precision drift compensation may not be performed in some cases. Specifically, the sample drift speed may vary. An example of time variation of a sample drift after stopping the specimen stage in the specimen stage of the STEM/SEM is shown in FIG. 16.

Firstly, directly after stopping the specimen stage, the specimen is drifted at the speed of several tens nm/minute due to the inertia. The drift is converged in a few minutes, and then the sample drift which is caused by stress relaxation of the components of the stage (for example, o-ring) or temperature change due to the electronic beam irradiation is continued at several nm/minute.

Generally, five minute waiting time is required until the speed of sample drift under capture is converged substantially at a constant status. In the high magnification image capturing according to the related art, since the capturing is performed after manually performing the fine adjustment of a focal point or astigmatism, a time of approximately five minutes were always set between the specimen stage stop and capturing.

However, by the automation of recent various adjustment methods, the adjustment time is shortened to one or less minute. Therefore, even in the state where the sample drift speed is varied, the sample drift compensation is needed. This is because in the case of capturing plural images at a high magnification such as CT rotary series image capturing or device length measurement by the STEM, if the waiting time until the sample drift speed is converged is set to 5 minute, TAT is significantly lowered. Therefore, even though the sample drift speed is varied, it is required to perform high precision compensation.

The present invention is made in consideration of the above-mentioned knowledge. The embodiments will be described below.

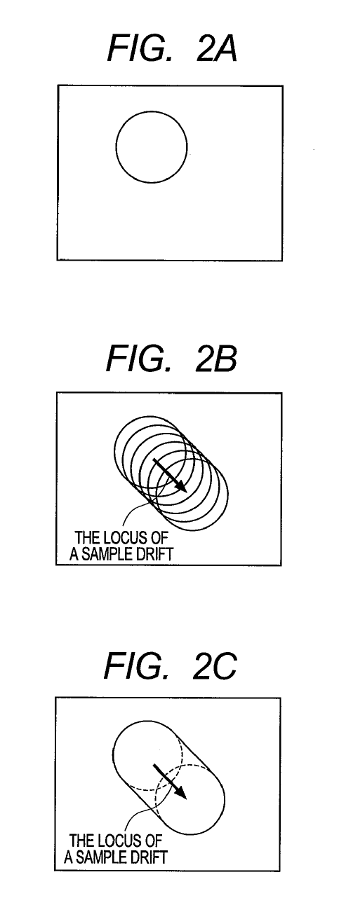

A basic flow of a sample drift compensation system using a charged particle beam microscope according to an embodiment is shown in FIG. 3. The sample drift compensation system includes step 1 for obtaining an approximation function of a sample drift before capturing a temporary image, step 2 for capturing the temporary image while carrying out drift compensation, and step 3 for creating a final image which reduces the influence of the sample drift from the temporary image.

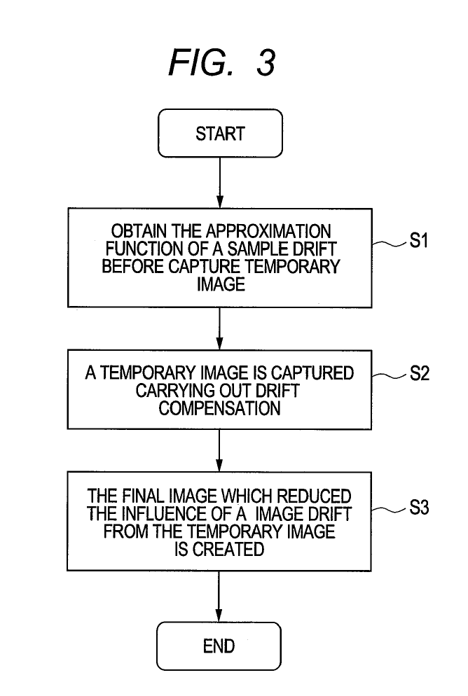

Firstly, a flow in the case of capturing the temporary image using a slow scan method is shown in FIG. 4. In step 1 of obtaining the approximation function of the sample drift before capturing the temporary image, the sample drift speed was obtained from the image drift (visual field shift) amount for two sheets of images in the related art. However, according to the present invention, plural visual field shift amounts from three or more sheets of images are measured and the locus of the sample drift is obtained. Therefore, the approximation function of the sample drift is obtained from the locus.

Hereinafter, the process of obtaining the approximation function will be described. By using an image captured first as a reference image and an image capture thereafter as an input image, the visual field shift amount with respect to the reference image is obtained and compensated using the image shift. Since the visual field follows the sample drift by the image shift, the locus of the image shift control value can be considered as the locus of the sample drift.

The approximation function of the sample drift is obtained from the locus. An appropriate degree of a polynomial expression that uses the time as a variable is used for the approximation function. A trigonometric function, an exponential function, and a logarithmic function may be used. By describing using the approximation function, the sample drift that temporally changes can be compensated with high precision. Therefore, one of the problems can be solved.

Further, since the sample drift is described with the approximation function, the influence of the visual field shift measuring error which is another problem is reduced. Since it can be assumed that the sample drift refers to a smooth movement, the high frequency component included in the locus of the sample drift can be considered as the visual field shift measuring error. The high frequency component is suppressed by fitting with the approximation function, and the actual sample drift can be described more accurately.

In order to suppress the high frequency component, a smoothing processing such as averaging or frequency processing such as a low-pass filter may be carried out before fitting. As necessary, the approximation function may be appropriately compensated. For example, the sample drift before capture is approximated to a linear equation to obtain a sample drift vector. By using a value obtained by applying an appropriate coefficient, for example, 0.5 to 1.0, the compensation under capture is carried out. Even though it is assumed that the speed of the sample drift is gradually decreased as same as directly after stopping the specimen stage, it is effective in a case where the visual field shift measuring error is large and the fitting result is unstable when the locus of the sample drift is approximated to two or larger degree of polynomial expression. The coefficient is adjusted in accordance with the time after stopping the stage or the characteristics of the stage.

In step 2 (FIG. 3), the temporary image is captured while controlling the image shift so as to offset the sample drift on the basis of the obtained approximation function. In step 3, a final image which reduces the influence of the sample drift from the temporary image is created.

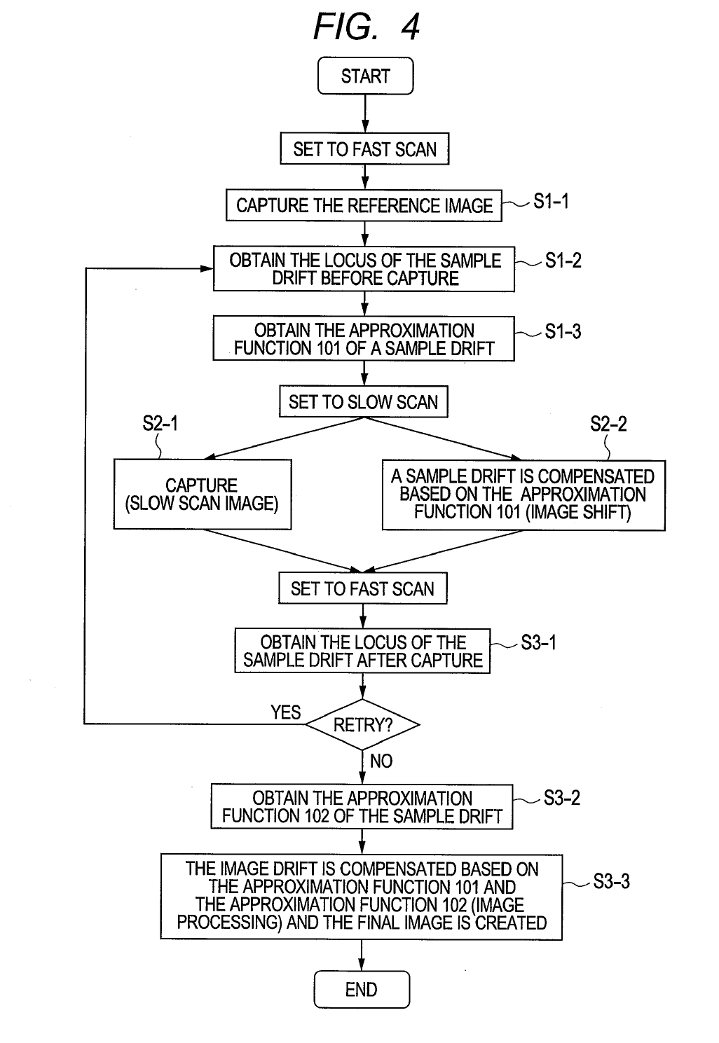

As shown in FIG. 5, since the sample drift under capture is compensated by the approximation function 101 obtained from the locus of the sample drift before capture, a shift from the actual sample drift may occur. Therefore, the sample drift is measured even after capturing the temporary image, and the approximation function 102 is calculated from the locus of the sample drift before and after capture. The difference between the approximation function 101 and the approximation function 102 is considered drift between the actual drift and the compensation amount, and the approximation function of the image drift (visual field shift) under capture is obtained from the drift. The image distortion caused by the visual field shift is compensated by image processing using the approximation function.

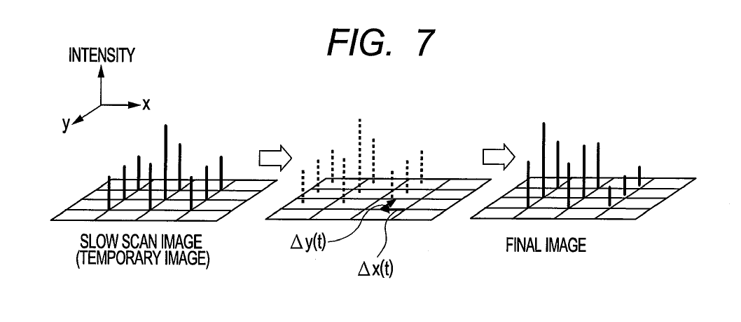

The processes will be described with reference to FIG. 7. The intensity of respective pixels in a discrete image is set to 1 (xn, yn). xn and yn are integers. Compensation data that moves by a visual field shift amount (ΔX(t), Δy(t)) at a capturing time t of each pixel is created. Since (ΔX(t), Δy(t)) is the real number, the intensity of each pixel is obtained by the interpolation to create the final image. Further, when the difference between the actual sample drift and the compensation amount is small, the compensation by the image processing may be omitted. Further, the compensation may be performed using only the image processing while omitting the compensation by the image shift.

Next, an example of capturing the temporary image using a fast scan method is shown. Step 1 is similar to the case of the slow scan method. In step 2, plural frame integration images in which plural fast scan images are integrated are captured and stored while compensating the sample drift by the image shift. The frame integration images also include one sheet of integrated image. In step 3, visual field shift amount of each of the frame integration images with respect to the reference image is obtained, and the final image is created by integrating the frame integration image while compensating the image shift.

In the related art, the measured visual field shift amount is converted into the direct compensation amount. In contrast, according to the embodiment, the locus of the visual field shift is obtained and the approximation function 103 of the visual field shift is obtained from the locus. The measured locus is considered as a composition of a smooth curve due to the sample drift and slight movement due to the visual field shift measuring error. The approximation function whose a high frequency component is suppressed from the locus is obtained which can suppress the influence of the visual field shift measuring error.

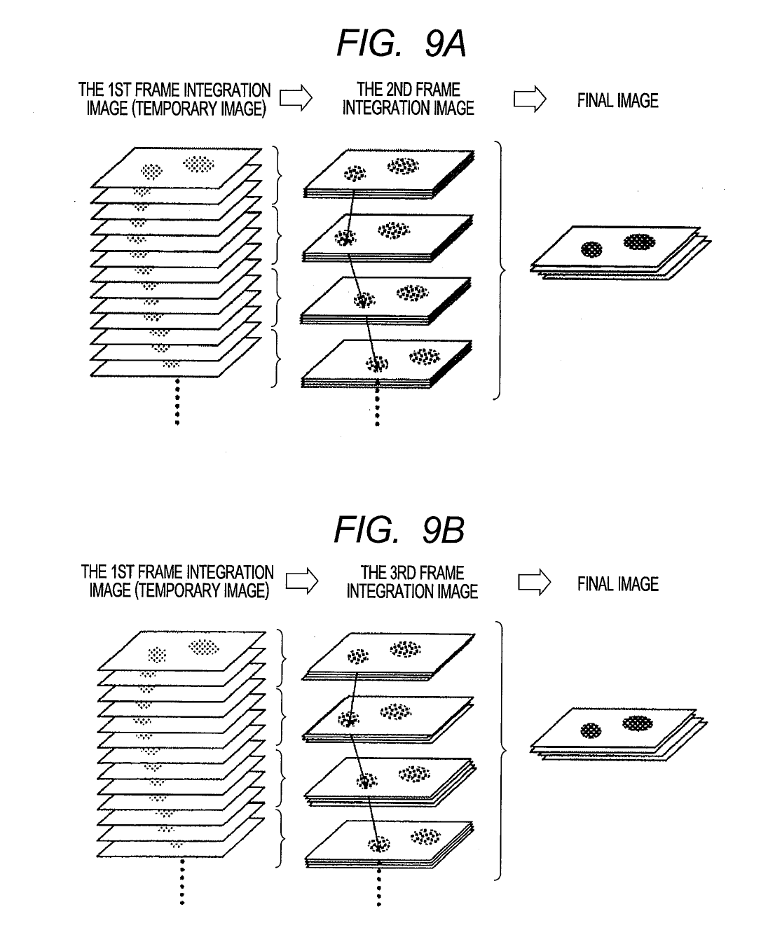

In order to suppress the high frequency component, smoothing processing such as averaging or frequency processing by a low-pass filter, or fitting processing to an appropriate degree of a polynomial expression may be applied. Further, by using the approximation function, the compensation shown in FIG. 9 is possible. The number of integrated sheets of the frame integration image stored in step 2 is reduced, and if possible, one sheet of image is integrated to store a first frame integration image. Since the first frame integration image has a low SN whose visual field shift by the image processing is difficult to be measured, the first frame integration image is integrated for a predetermined number of images, and a second frame integration image having a SN that can measure the visual field shift is created. A locus of the visual field shift is obtained by using the second frame integration image and the approximation function of the visual field shift is obtained.

Next, as shown in FIG. 9B, the visual field shift amount of the first frame integration image is calculated using the approximation function and a third frame integration image is created by integrating the image shift while compensating the visual field shift. Since the image blurring due to the visual field shift is reduced, the third frame integration image is sharper than the second frame integration image. When the third frame integration image is used, the measuring error of the visual field shift amount is reduced. Therefore, the locus of the visual field shift is measured again using the third frame integration image and the approximation function of the visual field shift is obtained.

By repeating the above steps until the approximation function is converged, the image blurring due to the sample drift can be significantly reduced. Further, if the sample drift amount is small, the drift measurement before capture in step 1 and compensation of drift due to the image shift under capture in step 2 can be omitted. The case where the sample drift amount is small refers to the case where the drift amount is below measuring error.

In the related art, the visual field shift amount is directly converted into the compensation amount or the sample drift speed. In contrast, in the embodiment, the approximation function used for the sample drift compensation is obtained from the plural visual field shift amounts, and the visual field shift is compensated using the approximation function. One of the effects obtained using the approximation function is to reduce the influence of the visual field shift measuring error. Like the related art, if the visual field shift amount between the images is converted into the direct sample drift, the visual field shift measuring error is directly reflected into the compensation error. By using plural visual field shift measurement results, random measuring errors can be offset (smoothened), and the compensation precision is improved.

Another effect of compensation based on the approximation function is that it is possible to perform high precision drift compensation even when the sample drift speed is temporally changed. In a method of the related art, it is necessary to set the waiting time until the sample drift becomes substantially constant. In a case where the movement of a specimen stage and capture are repeated such as automatic capturing of CT rotary series images, management of a sectional size of a semiconductor device, or a search of a defected portion, if the waiting time until the sample drift becomes substantially constant is set, the measurement TAT is significantly lowered. According to the embodiment, the waiting time can be reduced without deteriorating the compensation precision.

Further, when the image contrast caused by the charge is observed by observing the SEM, if the waiting time until the sample drift is substantially constant is set, a desired image contrast may not be obtained. Even though the sample drift is temporally changed, the drift compensation needs to be applied. According to the embodiment, the precision for drift compensation is high. As described above, according to the embodiment, the high precision of sample drift compensation and the improvement of TAT can be achieved, and the efficiency of measurement, inspection, analysis of a nanodevice or a nanomaterial by an electron microscope is significantly improved.

Hereinafter, embodiments will be described in detail.

### First Embodiment

The embodiment shows an example in which an automatic compensation system of a sample drift is applied to the slow scan capturing of the STEM. The fact that is described in the section of Preferred Embodiment of the Invention but not described in the embodiment is the same as in Preferred Embodiment of the Invention.

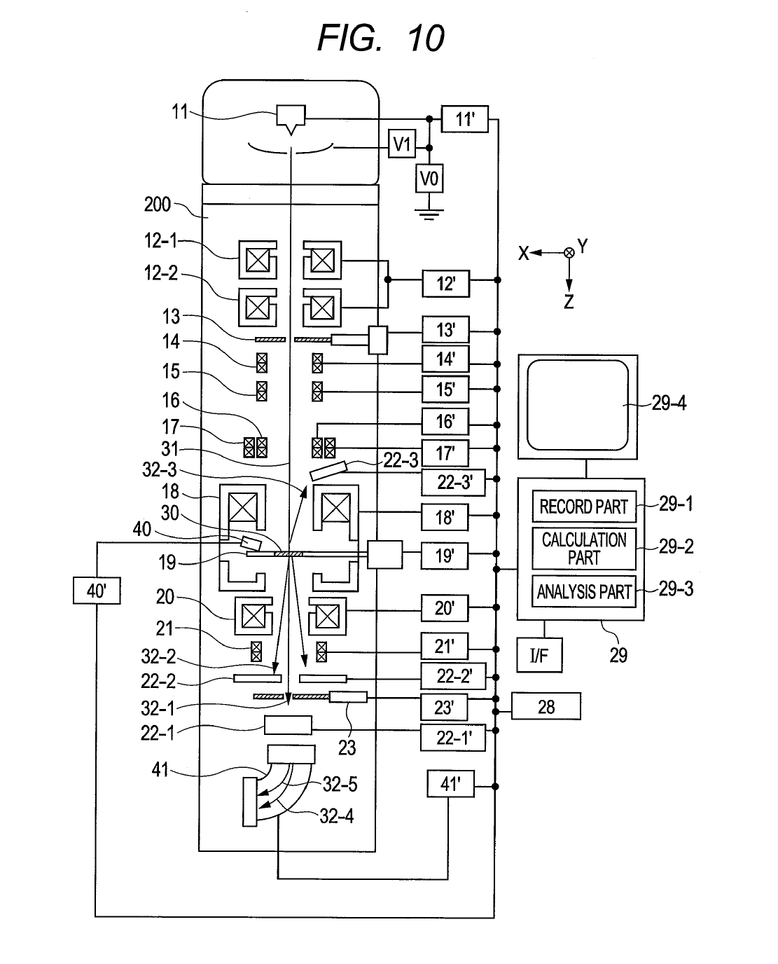

The basic configuration of an STEM/SEM used in the embodiment is shown in FIG. 10. The STEM/SEM includes an electron gun 11 that generates a primary electron beam 31 and a control unit 11′ thereof, condenser lenses 12-1 and 12-2 that converge the primary electron beam 31 and a control unit 12′ thereof, an aperture 13 that controls a spread angle of the primary electron beam 31 and a control unit 13′ thereof, an alignment deflector 14 that controls an incident angle with respect to a specimen 30 and a control unit 14′ thereof, a stigmator 15 that compensates the beam shape of the primary electron beam 31 that is incident onto the specimen 30 and a control unit 15′ thereof, an image shift deflector 16 that adjusts the irradiation area of the primary electron beam 31 that is incident onto the specimen 30 and a control unit 16′ thereof, a scanning deflector 17 that raster-scans the primary electron beam 31 that is incident onto the specimen 30 and a control unit 17′, an objective lens 18 that adjusts the focal position of the primary electron beam 31 with respect to the specimen 30 and a control unit 18′, a specimen stage 19 that sets the position and a rotation angle of the specimen 30 with respect to the incident electron beam 31 and a control circuit 19′ thereof, an electron detector 22 that detects the electron beam 32 generated from the specimen 30 and a control unit thereof, a projective lens 20 that projects the electron beam 32 onto the electron beam detector 22 and a control unit thereof 20′, a deflector 21 that deflects the electron beam 32 and a control unit 21′ thereof, an aperture 23 that controls a spread angle of the electron beam 32 and a control unit thereof 23′, an image formation unit 28 that forms an STEM/SEM image from an output signal of the electron beam deflector and a raster scan signal, and a computer 29 with a control program and an image processing program.

A record part 29-1 that records plural images, a calculation part 29-2 that measures a visual field shift amount between the images, an analysis part 29-3 that obtains an approximation function used for visual field shift compensation, and a display part 29-4 that displays the images, a calculation result, and an analysis result are mounted in the computer 29. The respective control units and the image formation unit are controlled by commands from the computer 29.

The device includes plural electron beam detectors 22, a bright image detector 22-1 that detects a low angle scatter electron 32-1, among the electron beams emitted to the front of the specimen 30, a dark image detector 22-2 that detects a high angle scatter electron 32-2, and a detector 22-3 that detects a reflective electron and a secondary electron 32-3 that are emitted to the back of the specimen 30. Control units 22-1′, 22-2′, and 22-3′ are provided so as to correspond to the respective detectors.

An image formed by an electron emitted to the front of the specimen 30 is referred to as an STEM image, and an image formed by an electron emitted to the back of the specimen 30 is referred to as an SEM image. Further, a transmission electron beam may be split into an elastic scattered transmission electron beam 32-4 and a nonelastic scattered transmission electron beam 32-5 by an energy loss electron spectroscope 41 and a control unit 41′ thereof and measured. An X-ray generated from the specimen may be measured by an energy dispersive X-ray spectroscope 40 and a control unit 40′ thereof. It is possible to analyze the composition or chemical bond status of the specimen by using the energy dispersive X-ray spectroscope 40 or the energy loss electron spectroscope 41.

Measurement of a micro region spectrum by stopping the scanning of the first electron 31 is referred to as a point analysis and measurement of composition or distribution of chemical bond status by synchronizing the scan of the primary electron beam with a predetermined energy band signal is referred to as a surface analysis. An image obtained by the surface analysis of the energy dispersive X-ray spectroscope 40 is referred to as an EDX image, and an image obtained by the surface analysis of the energy loss electron spectroscope 41 is referred to as an EELS image.

In the embodiment, even though only the case that the drift compensation system is applied to the STEM image is described, the system may also be applied to other signal image. A direction that is substantially parallel to an optical axis of a housing 200 is a Z axis, and a plane that is substantially perpendicular to the optical axis is an XY plane.

FIG. 4 shows a flow of sample drift compensation in the case of capturing the temporary image using a slow scan method. First, a reference image that is used for visual field shift measurement is captured (S1-1). An STEM has two image formation modes of a display mode and a storage mode. The temporary image refers to an image to be stored in an electron file and a high quality image is captured by setting a time to approximately 10 seconds. The display image is an image to be displayed on a monitor. Even though the image quality is low, an image can be input to the image processing device at any time. The display image is used for sample drift measurement.

In the case of the display image according to the slow scan method, since a value of each pixel in the image is sequentially updated by the electron beam scanning, if there is sample drift, different images are captured above and below the image. Therefore, if the scanning start and the timing input to the image processing device are not synchronized, the visual field shift is measured by an image obtained by capturing an image in which different visual fields are captured above and below the image. Even though the timing can be synchronized by monitoring the scanning waveform, the system may be complicated.

In the meantime, the display image according to the fast scan method is a frame integration image of n recently fast scanned images. If there is a sample drift, the display image is blurred, but the timing input to the image processing device needs not be synchronized with the electron beam scanning. That is, the capturing timing may be freely set.

For the above-mentioned reason, a display image using the fast scan method is used for an image for visual field shift measurement. Thereafter, if not specifically mentioned except for capturing, the image for visual field shift measurement is a display image using the fast scan method.

An image is captured at an interval of approximately one second after capturing the reference image and the visual field shift amount with respect to the reference image is measured by image processing. The visual field is moved so as to offset the visual field shift with respect to the reference image using the image shift. Since the visual field moves following the sample drift, the locus of a control value of the image shift may be considered as the locus of the sample drift (S1-2).

In order to measure the visual field shift, a general purpose image processing such as a standardized cross-correlation method, a phase only correlation method, or a least square method is used. Since the method suitable for visual field shift measurement is varied depending on the input image, an appropriate method is selected by referring to the visual field shift measuring error or a correlation value. Further, in the case of a device in which a piezo stage for a fine movement of the specimen stage is mounted, the sample drift compensation may be carried out by the piezo stage not by the image shift. By using the piezo stage, the movement distance of 1 μm can be controlled in the order of 0.1 nm.

Next, an approximation function 101 of the sample drift is obtained from the locus of the sample drift (S1-3). It is assumed that the sample drift smoothly moves, and the slight movement occurring in the locus of the measured sample drift is considered as a visual field shift measurement error. If the locus of the visual field shift is approximated using a complex expression, the result is unstable. Therefore, as the approximation function, two or lower degree of polynomial expression using a time as a variable is suitable.

By fitting to the approximation function, the high frequency component is suppressed, such that an actual sample drift may be more precisely described. In order to suppress the high frequency component, a smoothing processing such as averaging or frequency processing such as a low-pass filter may be carried out before fitting.

As necessary, the approximation function obtained by fitting may be appropriately compensated. For example, the sample drift before capture is approximated to a linear equation to obtain a sample drift speed. Using a value obtained by applying an appropriate coefficient, for example, 0.5 to 1.0 to the sample drift speed, the compensation during the capturing is carried out. Even though it is assumed that the sample drift speed is gradually decreased as same as directly after stopping the specimen stage, if the visual field shift measuring error is large and the locus of the sample drift is approximated to two or larger degree of polynomial expression, it is effective when the fitting result is unstable. The coefficient is adjusted in accordance with the time after stopping the stage or the characteristics of the stage.

Further, since not all result measured by the image processing is used, but only a part of measurement result is set to be selected, for estimation of the approximation function, the compensation precision is improved. For example, the visual field shift measurement result in which the correlation value between the images is below a predetermined value is not used for the estimation of the approximation function, and a result that is far from the visual field shift measurement result before and after capture is not used for the estimation of the approximation function.

In addition, in a case where the compensation is carried out again because the sample drift compensation error is large, the visual field shift amount that is measured at first is the sample drift between S3-1 and S1-2 of FIG. 4. Therefore, after compensating the visual field shift amount using the image shift, the measurement of the locus of the sample drift is set to begin. It is determined which approximation function is suitable depending on whether the visual field shift amount becomes the least by measuring the visual field shift amount with respect to the reference image after capturing the temporary image.

Next, the temporary image is captured while compensating the drift (step 2). The slow scan method is set as a capturing method, and the temporary image is captured (S2-1) while controlling the image shift based on the approximation function of the sample drift (S2-2).

The image shift control may be carried out by transmitting a control value obtained from the approximation function at an equal interval of time, for example, for every 0.5 second. Further, the image shift control may be carried out by obtaining a time when the control value variation from the equal movement amount for example, the approximation function, becomes 0.1 pixel, and transmitting the control value at the calculated time. If the equal time is set, as the magnification is higher, the transmission interval is preferably set to be smaller. Therefore, the compensation interval is linked to the magnification to be automatically adjusted.

Finally, a final image in which the influence of the sample drift from the temporary image is reduced is created (step 3). As shown in FIG. 5, if the sample drift under capture is compensated by the approximation function 101 obtained from the locus of the sample drift before capture, the sample drift may be deviated from the actual sample drift.

Therefore, the sample drift is measured even after capturing the temporary image, and an approximation function 101 is obtained from the locus of the sample drift before and after capture (S3-2). The difference between the approximation function 102 and the approximation function 101 is considered as a deviation between the actual sample drift and the predicted drift, and an approximation function of a visual field shift under capture is obtained from the deviation. Based on the approximation function, the image distortion caused by the visual field shift is compensated by the image processing (S3-3).

When the approximation function 102 is obtained, an interpolation function generated by the spline interpolation may be used other than the approximation function fitting used in step 1. In step 1, since the sample drift under capture is predicted from the locus before capture, it is expected that the deviation from the actual sample drift may be reduced by approximating to the polynomial expression compared with extrapolating using the interpolation formula.

In the meantime, in step 3, since the sample drift under capture is predicted from the locus before and after capture, it is considered that the sample drift under capture may be precisely predicted by interpolation by the interpolation formula. Which approximation function is used is selected by referring to a root mean square error between the locus of the sample drift and the approximation function.

Next, the visual field shift amounts Δx(t) and Δy(t) at respective times are obtained from the approximation function 101 and the approximation function 102. A method for creating a final image from the temporary image using the obtained visual field shift amounts Δx(t) and Δy(t) will be described with reference to FIG. 7. The intensity of each pixel in a discrete image is set to I(xn, yn). xn and yn are integers. Compensation data that moves by a visual field shift amounts (ΔX(t), Δy(t)) at a capturing time t of each pixel is created. Since (ΔX(t), Δy(t)) is the real number, the intensity of each pixel is calculated by the interpolation to create the final image. Therefore, it was possible to obtain an image in which image blurring or distortion is significantly reduced. Further, as a result of measuring the size of a pattern formed on the surface of the specimen using the image created as described above, the result in which an error of several nm caused by the image blurring or image distortion is reduced was obtained.

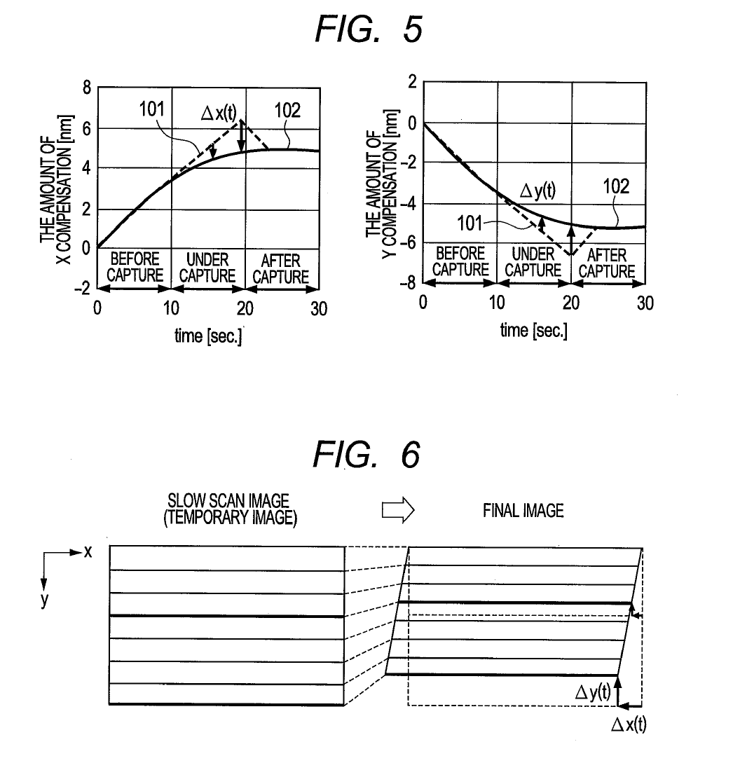

If both the approximation function 101 and the approximation function 102 use a linear expression, as shown in FIG. 6, the final image may be created such that the temporary image is affine-transformed with respect to the drift amount in the x direction and the temporary image is magnified or contracted with respect to the drift amount in the y direction.

Without carrying out the distortion compensation by image processing, if there is difference between the approximation function and the actual sample drift, a flow of recapturing may be adopted. One sheet of image for visual field shift measurement is captured after capture, and it is checked whether the visual field shift amount is in an acceptable range. If the visual field shift amount is out of the acceptable range, recapturing is carried out (FIG. 4). Further, a flow in which the distortion compensation is not carried out for the image within the range, but the distortion compensation is carried out only for the image out of the range may be used. Further, without carrying out the drift compensation under capture by the image shift, only drift compensation after capture by the image processing may be carried out.

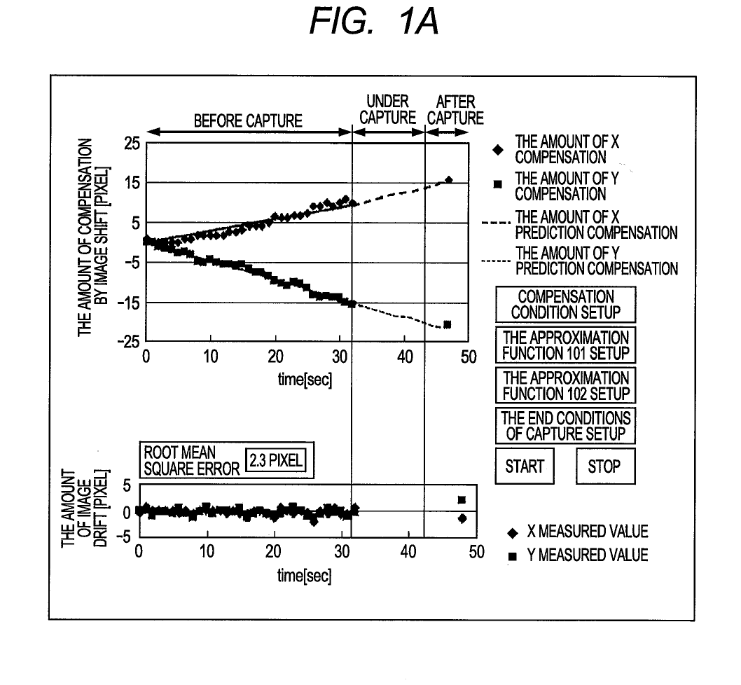

A screen for setting the above flow or the approximation function is shown in FIG. 1A to 1C. On a main screen of FIG. 1A, a graph that represents the image drift (visual field shift) amount measured at every timing and the compensation amount by the image shift, that is, the locus of the sample drift and the approximation function, a setup button for opening a sub window to set the compensation conditions or approximation functions, a start button that indicates the start of the drift compensation, and a stop button that indicates the stop are arranged.

If the setup button is clicked, sub screens corresponding to the respective buttons are displayed (FIG. 1B). If the compensation condition setup button is clicked, a screen for inputting the number of drift compensation and the compensation interval before and after capture and the capturing time and the compensation interval is displayed. The unit of compensation interval under capture may be set as a time or a distance. In the approximation function setup, a function of approximating the locus of the sample drift is indicated. When the approximation method is clicked, available approximation methods are displayed. Therefore, drag and drop is performed to the indicated method and the method is selected.

A sub screen for setting a parameter of the selected approximation method is displayed (FIG. 1C). A required parameter is set and then the sub screen is closed. If the smoothing is clicked, a sub screen for setting a smoothing parameter is displayed. Then, a required parameter is set and the sub screen is closed.

In the capturing completion condition setup, first, whether to automatically or manually determine the recapturing is selected (FIG. 1B). When the automatic determination is selected, the tolerance level (acceptable range) of the image drift (visual field shift) and the measurement repetition maximum are inputted. The acceptable range of the visual field shift may be set to a fixed value. Further, the acceptable range may be set to a reference varied depending on the specimen, such as 3σ of the visual field shift amount, a square root error of the approximation function with respect to the locus of the sample drift or the like. If the visual field shift is below the acceptable range, since the re-compensation is required, the process proceeds to next step (S3-2). If the visual field shift amount is above the acceptable range, the steps from the drift measurement before capture (S1-2) are carried out again (FIG. 4).

When saving of all images is not selected, and the repetition maximum is 2 or larger, the approximation function 102 is obtained by measuring the locus of the sample drift after capture only at the final step and the number of compensation is set to once to determine only whether the visual field shift amount is within the tolerance level (acceptable range). At the final stage step, if the sample drift amount is above the distorted compensation scope (compensation range), the locus of the sample drift after capture is measured with the number of compensation and compensation interval set at the compensation condition setup and the distortion compensation is carried out by the image processing. In the case of setting the distorted compensation range to an unlimited value, the distortion compensation is not carried out for all images.

When storing all images is selected, all images captured in step S2-1 are stored. Further, if the specimen drift amount is above the distorted compensation range, the locus of the sample drift after capture is measured at all steps. The distortion compensation by the image processing is carried out for each temporary image capturing to obtain plural final images. From among the above images, the most precision image may be selected, and a much higher SN image may be created by integrating the images.

In the case of selecting manual, it is impossible to set the visual field shift acceptable range, the measurement repetition maximum, and the distorted compensation range. When the capturing is completed, the locus of the sample drift is measured with the number of compensation and compensation interval after capture and then displayed on the main screen. Further, since a screen for inputting whether to perform re-measurement or distortion compensation is displayed, a user sees the measurement result and then inputs the next processing.

Further, when a user is registered by being divided into a general user and a manager, the setup button may be displayed only on the screen for a manager, but may not be displayed on the screen for a general user. This is to prevent the drift compensation error caused by setting an inappropriate parameter by a beginner. Further, the manager may create a recipe and the general user may read the designated recipe. For example, even though CT rotary series image capturing and the device size measurement by the STEM capture plural images at a high magnification, a kind of specimen folder used or a moving order of the specimen stage is different from each other. The parameter of the sample drift compensation system may be adjusted in accordance with the respective conditions and then stored as a recipe to be read at the time of using.

According to the embodiment, it is possible to provide an STEM/SEM that is not influenced or little influenced by the sample drift even though the visual field diameter is the high magnification of approximately 250 nm×250 nm, and a measurement method using the same.

### Second Embodiment

A second embodiment uses the device shown in FIG. 10 similarly to the first embodiment and the temporary image is captured by a fast scan method. Further, a fact that is described in the first embodiment, but not described in the embodiment is the same as the first embodiment.

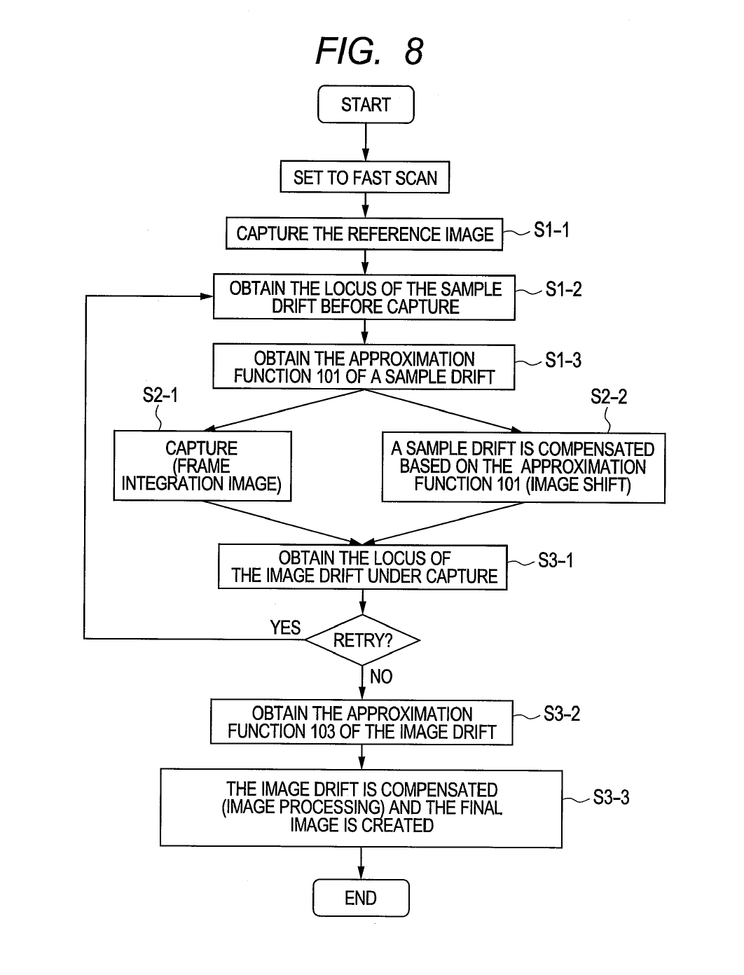

FIG. 8 shows a flow of sample drift compensation when the temporary image is captured by the fast scan method. A step of calculating an approximation function of a locus of a sample drift before capturing the temporary image (step 1) is almost the same as the first embodiment. In the second embodiment, when the temporary image is captured while compensating the sample drift by the image shift (step 2), a frame integration image in which a predetermined number of sheets of fast scan images are integrated is used as a temporary image. In step 3, the locus of the image drift (visual field shift) of the frame integration image with respect to the reference image is obtained (S3-1).

Further, when the blurring of the frame integration image is increased because the sample drift compensation in step 2 is deviated from the actual sample drift and the visual field shift amount cannot be measured, the steps from the sample drift measurement (S1-2) before capture are performed again. Even when the approximation function 103 of the visual field shift is calculated from the locus of the image drift (visual field shift) under capture (S3-2), the high frequency component generated in the measured locus is considered as a visual field shift measurement error and reduced by the computation. For example, a smoothing processing such as averaging is carried out on the locus. Further, a low-pass filter is applied to the locus. The locus may be approximated to a predetermined degree of polynomial expression. Plural processing, for example, the approximation to the polynomial expression may be carried out after smoothing or filter processing.

On the basis of the obtained approximation function, the frame integration image is integrated while compensating the image drift (visual field shift) to obtain a final image (S3-3). Thereby, it was possible to obtain an image in which image blurring or image distortion is significantly reduced. Further, as a result of measuring the size of a pattern formed on the surface of the specimen using the image created as described, the result in which an error of several nm caused by the image blurring or image distortion is reduced was obtained.

Furthermore, when a result that the sample drift speed is slow is obtained in step 1, the drift compensation by the image shift carried out in step 2 may be omitted. If it can be assumed that the sample drift speed is sufficiently slow, the sample drift measurement in step 1 may be omitted.

By describing the visual field shift with the approximation function, the processing shown in FIGS. 9A and 9B can also be carried out. The number of integrated sheets of the frame integration image stored in step 2 is reduced and if possible, only one sheet of image is integrated to store a first frame integration image.

Since the first frame integration image has low SN whose visual field shift caused by the image processing is difficult to be measured, the first frame integration image is integrated for every sheet, a second frame integration image of SN that can measure the visual field shift is created. A locus of the visual field shift with respect to the reference image is measured by using the second frame integration image and the approximation function 103 thereof is obtained.

An interpolation formula such as a spline interpolation is suitable for the approximation function 103. If the visual field shift measurement error is large, a polynomial expression approximation may be used. Further, the spline interpolation or the polynomial expression approximation may be applied after smoothing the locus. The approximation method is selected referring to a root mean square error between the locus and the approximation function.

Based on the calculated approximation function, a third frame integration image obtained by compensating the deviation between the first frame integration images is created. Since the image blurring by the sample drift is reduced, the third frame integration image is sharper than the second frame integration image. When the third frame integration image is used, the visual field shift measurement error is reduced. Therefore, the locus of the visual field shift is re-measured by using the third frame integration image, and the approximation function 103 is calculated. By repeating the above steps until the approximation function 103 is converged, the image blurring due to the sample drift can be significantly reduced. Based on the converged approximation function 103, the third frame integration image is integrated while compensating the visual field shift to create a final image.

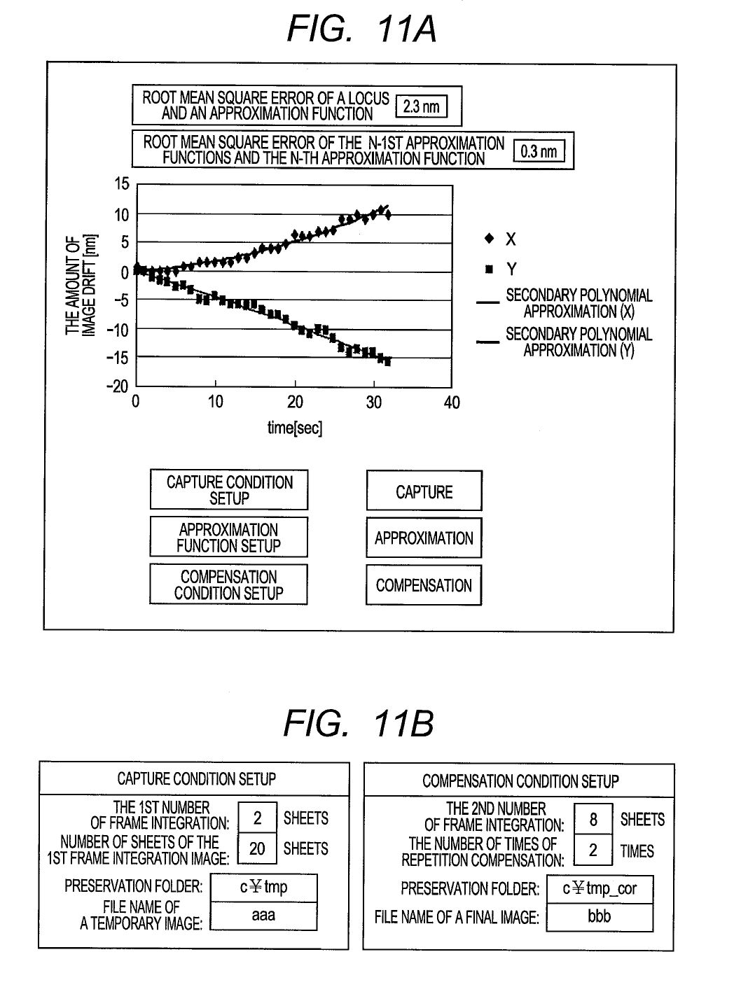

Finally, an example of a display screen used in carrying out the sample drift compensation is shown in FIGS. 11A and 11B. The screen is used when omitting the sample drift compensation in step 1 and step 2 and carrying out only a process of creating a final image in which the influence of the sample drift from the temporary image is reduced in step 3. On a main screen of FIG. 11A, a graph that represents the locus of the image drift (visual field shift) of the frame integration image with respect to the reference image and the approximation function, a setup button for opening a sub window to set a capture condition, approximation functions, and compensation conditions, and a button for instructing to capture and compensation are arranged.

If the setup button is clicked, sub screens corresponding to the respective buttons are displayed (FIG. 11B). If the capture condition setup button is clicked, a screen for inputting the first number of frame integration, the number of sheets of the first frame integration image, a preservation folder (storing folder), and a file name is displayed and the respective values thereof is inputted.

If the capture button is clicked, the capture starts. Since the sub windows for the approximation function setup is the same as the first embodiment, the description thereof is omitted. If the button for the compensation condition setup is clicked, a screen for inputting the second or third number of frame integration, the number of times of repetition compensation shown in FIGS. 9A and 9B, a folder for saving a file after compensation, and a file name is displayed, and the respective values thereof are inputted.

As the second number of frame integration, only multiple of the first number of frame integration can be input. Further, if the first number of frame integration is equal to the second number of frame integration, the input of the number of times of repetition becomes invalid. If the compensation button is clicked, the second frame integration image is created from the first frame integration image, the visual field shift amount of the second frame integration image with respect to the reference image is measured, such that the locus of the visual field shift is displayed.

If the second number of frame integration is equal to the first number of frame integration, a final image in which the second frame integration image is integrated based on the approximation function 103 of the visual field shift while compensating the visual field shift is created. If the second number of frame integration is larger than the first number of frame integration and the number of times of repetition is once, a final image in which the first frame integration image is integrated based on the approximation function 103 of the visual field shift while compensating the visual field shift is created.

If the number of times of repetition is twice or more, a third frame integration image in which the first frame integration image is integrated based on the approximation function 103 of the visual field shift while compensating the visual field shift is formed and then stored in a folder designated according to the compensation condition. Further, the visual field shift amount of the third frame integration image with respect to the reference image is measured, and then the locus of the second visual field shift is displayed on the main screen. A final image in which the first frame integration image is integrated based on a second approximation function obtained from a second locus while compensating the visual field shift is formed.

If the number of times of repetition is three times or more, a fourth frame integration image in which the first frame integration image is integrated based on a second approximation function 103 by compensating the visual field shift is formed, and the above processes are repeated. Since a root mean square error between an n-th approximation function and an n−1-th approximation function is displayed on the main screen, the number of times of repetition n is optimized so as to converge the error.

According to the embodiment, it is possible to provide an STEM/SEM that is not influenced or little influenced by the sample drift even though the visual field diameter is a high magnification of 250 nm×250 nm, and a measurement method using the same.

### Third Embodiment

A third embodiment uses the device shown in FIG. 10 similarly to the first embodiment. In step 2, after storing several lines using a slow scan method, the slow scan method is switched to a fast scan method to measure the visual field shift amount with respect to the reference image. Thereafter, an example that by repeating a process of storing several lines of data by switching to the slow scan method, a temporary image is obtained will be described.

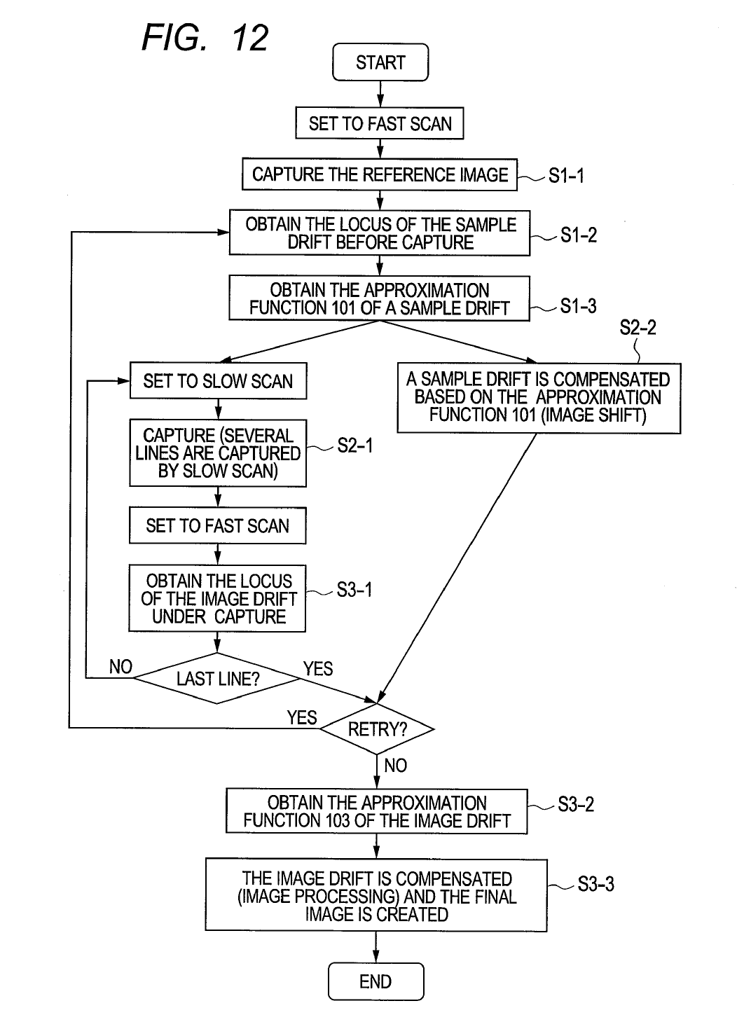

The sample drift compensation flow in this case is shown in FIG. 12. A step of obtaining an approximation function of a locus of a sample drift before capturing the temporary image (step 1) is substantially the same as the first embodiment. In the third embodiment, when the temporary image is captured while compensating the sample drift by the image shift, after storing several lines using the slow scan method (S2-1), the scan method is switched to the fast scan method, such that the image drift (visual field shift) amount with respect to the reference image is measured and stored together with the measuring time (S3-1).

Thereafter, the scan method is switched to the slow scan method, and a process of storing several lines of data is repeated to capture the temporary image. Further, since the sample drift compensation in step 2 is deviated from the actual sample drift, if the visual field shift under capture the temporary image is increased, the process restarts from the measuring of the sample drift before capture (S1-2).

After completing the capturing of the temporary image, an approximation function 103 of the image drift (visual field shift) is obtained (S3-2). By inputting the capturing time for each pixel of the temporary image to the approximation function, it is possible to obtain the visual field shift amount ΔX(t) and Δy (t). Since a method of creating a final image in which the image drift (visual field shift) is compensated from the temporary image was described with reference to FIG. 7 in first embodiment, the description thereof will be omitted. Therefore, it was possible to obtain an image in which image blurring or image distortion is significantly reduced. Further, as a result of measuring the size of a pattern formed on the surface of the specimen using the image created as described above, the result that an error of several nm caused by the image blurring or image distortion is reduced was obtained.

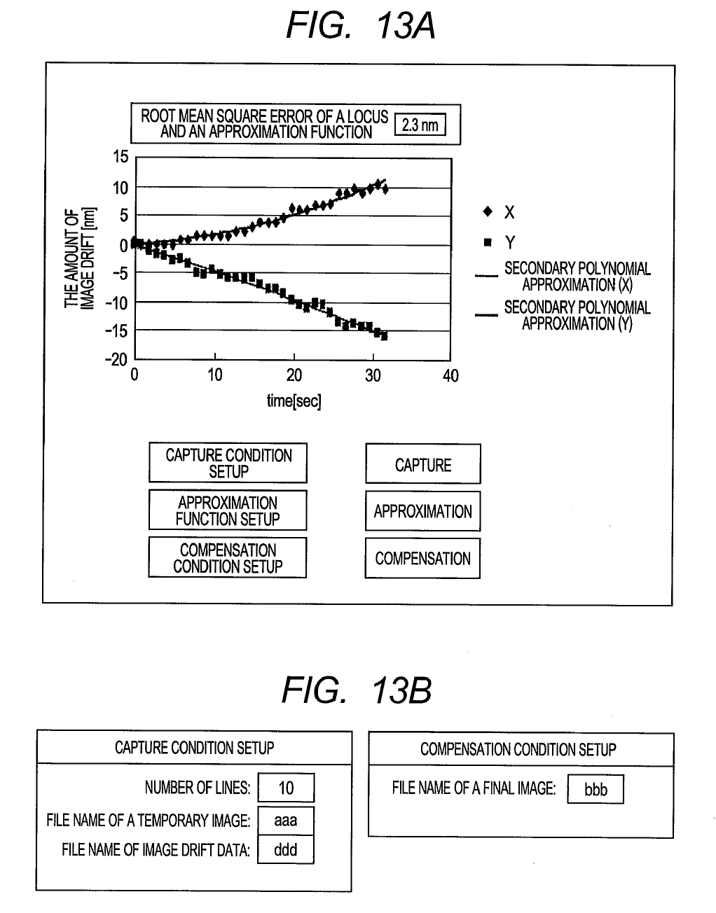

Finally, an example of a display screen used in carrying out the sample drift compensation is shown in FIGS. 13A and 13B. The screen is used when omitting the sample drift compensation in step 1 and step 2 and only reducing the image distortion caused by the sample drift in step 3 is carried out.

On a main screen of FIG. 13A, a graph that represents the locus of the image drift (visual field shift) and the approximation function, a setup button for opening a sub window to set a capture condition, approximation functions, and compensation conditions, and a button for instructing capture and compensation are arranged.

If the setup button is clicked, sub screens corresponding to the respective buttons are displayed (FIG. 13B). If the capture condition setup button is clicked, a screen for inputting the number of lines when capturing the temporary image, a file name of a temporary image, and a file name in which the image drift (visual field shift) is stored is displayed and the respective values thereof is inputted. If the capture button is clicked, the capture starts. Since the sub window for approximation function setup is the same as the first embodiment, the description thereof will be omitted. If the button for compensation condition setup is clicked, since a screen for inputting a file name to which an image after compensation is stored is displayed, a value is inputted. When the compensation button is clicked, the compensation described with reference to FIG. 7 of the first embodiment is carried out.

According to a method of the related art method in which the visual field shift amount is converted into the compensation amount as it is, it was required to frequently switch the capture of lines of the temporary image and the measurement of the visual field shift. It is because if the number of lines to be captured at once is increased, the connection parts between the lines become discrete. Further, there is deviation between the line capturing timing and the visual field shift measuring timing, such that there is further deviation between the measured visual field shift amount and the visual field shift amount under capturing the lines. The above-mentioned problem is solved by compensating the visual field shift using the approximation function.

Since it is possible to calculate the visual field shift amount for every pixel not for every captured line, the connection part of the lines is not discrete. The compensation may be carried out in consideration of the difference between the timing when the visual field shift amount is measured and the timing when the pixel is captured.

Therefore, even though the switching interval of the line capture and the visual field shift measurement is long, it is possible to compensate the image distortion caused by the sample drift with high precision. Further, if the switching interval is set to be long, the time required to compensate the visual field shift can be significantly shortened, such that the capture TAT is significantly improved.

According to the embodiment, it is possible to provide an STEM/SEM that is not influenced or little influenced by the sample drift even though the visual field diameter is a high magnification of 250 nm×250 nm and a measurement method using the same.

### Fourth Embodiment

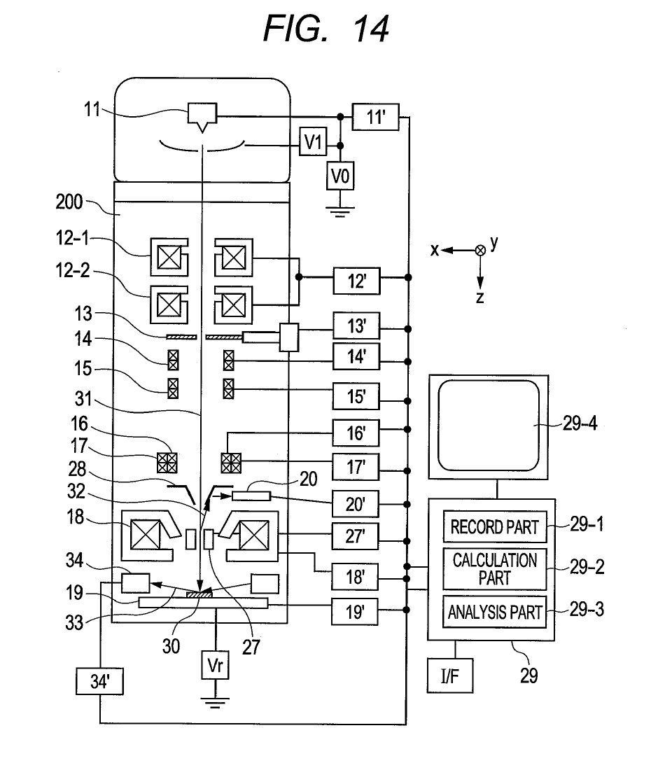

A fourth embodiment shows the sample drift compensation in SEM. The basic configuration of a wafer corresponding SEM used in this embodiment is shown in FIG. 14. The SEM includes an electron gun 11 that generates a primary electron beam 31 and a control unit 11′ that controls acceleration voltage and extraction voltage of the electron beam 31, condenser lenses 12-1 and 12-2 that adjust the convergence condition of the primary electron beam 31 and a control unit 12′ that controls a current value thereof, a condenser aperture 13 that controls a spread angle of the primary electron beam 31 and a control unit 13′ that controls the position of the condenser aperture, an alignment deflector 14 that adjusts an incident angle of the primary electron beam 31 incident onto a specimen 30 and a control unit 14′ that controls a current value thereof, a stigmator 15 that adjusts the beam shape of the primary electron beam 31 that is incident onto the specimen 30 and a control unit 15′ that controls a current value thereof, an image shift deflector 16 that adjusts the irradiation area of the primary electron beam 31 that is incident onto the specimen 30 and a control unit 16′ that controls a current value thereof, a scanning deflector 17 that raster-scans the primary electron beam 31 that is incident onto the specimen 30 and a control unit 17′ that controls a current value thereof, an objective lens 18 that adjusts the focal position of the primary electron beam 31 with respect to the specimen 30 and a control unit 18′ that controls a current value thereof, a specimen stage 19 that sets the position of a specimen 30 in a specimen compartment and a control circuit 19′ that controls the position thereof, an E×B deflector 27 that deflects the electron beam 32 emitted from the surface of the specimen in a predetermined direction and a control circuit 27′ that controls a current value thereof, a reflector 28 with which the deflected electron beam 32 collides, an electron detector 20 that detects the electron beam emitted from the reflector 28 and a control unit 20′ that controls a gain and an offset thereof, a specimen height sensor 34 that uses a laser beam 33, and a control circuit 34′ that controls the sensor, and a computer 29 with a SEM control program and an image processing program. Further, reference numeral 200 refers to a housing.

A recording part 29-1 that records plural images, a calculation part 29-2 that measures a visual field shift amount between the images, an analysis part 29-3 that obtains an approximation function used for visual field shift compensation, and a display part 29-4 that displays the images, a calculation result, and an analysis result are mounted in the computer 29. The respective control units are controlled by commands from the computer 29.

As compared with the STEM/SEM of the first embodiment, even though the device configuration is different from the first to three embodiments, for example, a high resolution image can be obtained by a retarding electrode (not shown) that increases the SN of the SEM image by the E×B deflector 27 or the reflector 28 even at a low acceleration, the sample drift compensation system described in the first to three embodiments can be applied thereto as it is. With this configuration, it is possible to obtain an image in which image blurring or image distortion is significantly reduced. Further, as a result of measuring the size of a pattern formed on the surface of the specimen using the image created as described above, the result that an error of several nm caused by the image blurring or image distortion is reduced was obtained.

According to the embodiment, it is possible to provide an STEM/SEM that is not influenced or little influenced by the sample drift even though the visual field diameter is a high magnification of 250 nm×250 nm and a measurement method using the same.

### Fifth Embodiment

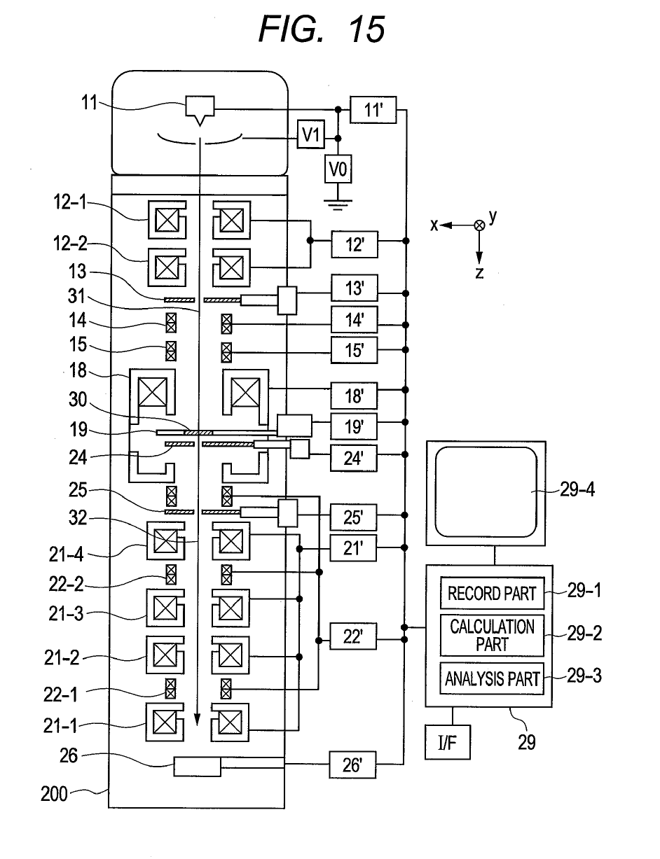

A fifth embodiment shows the sample drift compensation in TEM. The basic configuration of a TEM used in this embodiment is shown in FIG. 15. The TEM includes an electron gun 11 that generates a primary electron beam 31 and a control unit 11′ that controls acceleration voltage and extraction voltage of the electron beam 31, condenser lenses 12-1 and 12-2 that adjust the convergence condition of the primary electron beam 31, and a control unit 12′ that controls a current value thereof, a condenser aperture 13 that controls a spread angle of the primary electron beam 31 and a control unit 13′ that controls the position of the condenser aperture, an alignment deflector 14 that controls an incident angle of the primary electron beam 31 incident onto a specimen 30 and a control unit 14′ that controls a current value thereof, a stigmator 15 that adjusts the beam shape of the primary electron beam. 31 that is incident onto the specimen 30 and a control unit 15′ that controls a current value thereof, an objective lens 18 that adjusts the focal position of the primary electron beam 31 with respect to the specimen 30 and a control unit 18′ that controls a current value thereof, a specimen stage 19 that sets the position of the specimen 30 in a specimen compartment and a control circuit 19′ that controls the position thereof, an objective aperture 24 and a control unit 24′ thereof, a selected-area aperture 25 and a control unit 25′ thereof, a projective lenses 21-1, 21-2, 21-3, and 21-4 that projects a transmission electron beam 32 passing through the specimen 30 and a control unit 21′ that controls a current value thereof, alignment deflectors 22-1 and 22-2 that compensates axial deviation of the transmission electron beam 32 and a control unit 22′ thereof, an electron detective camera 26 that detects the transmission electron beam 32 and a control circuit 26′ that controls a gain or an offset thereof, and a computer 29 with a control program and an image processing program. Further, reference numeral 200 refers to a housing.

A record part 29-1 that records plural images, a calculation part 29-2 that measures a visual field shift amount between the images, an analysis part 29-3 that obtains an approximation function used for visual field shift compensation, and a display part 29-4 that displays the images, a calculation result, and an analysis result are mounted in the computer 29. The respective control units are controlled by commands from the computer 29.

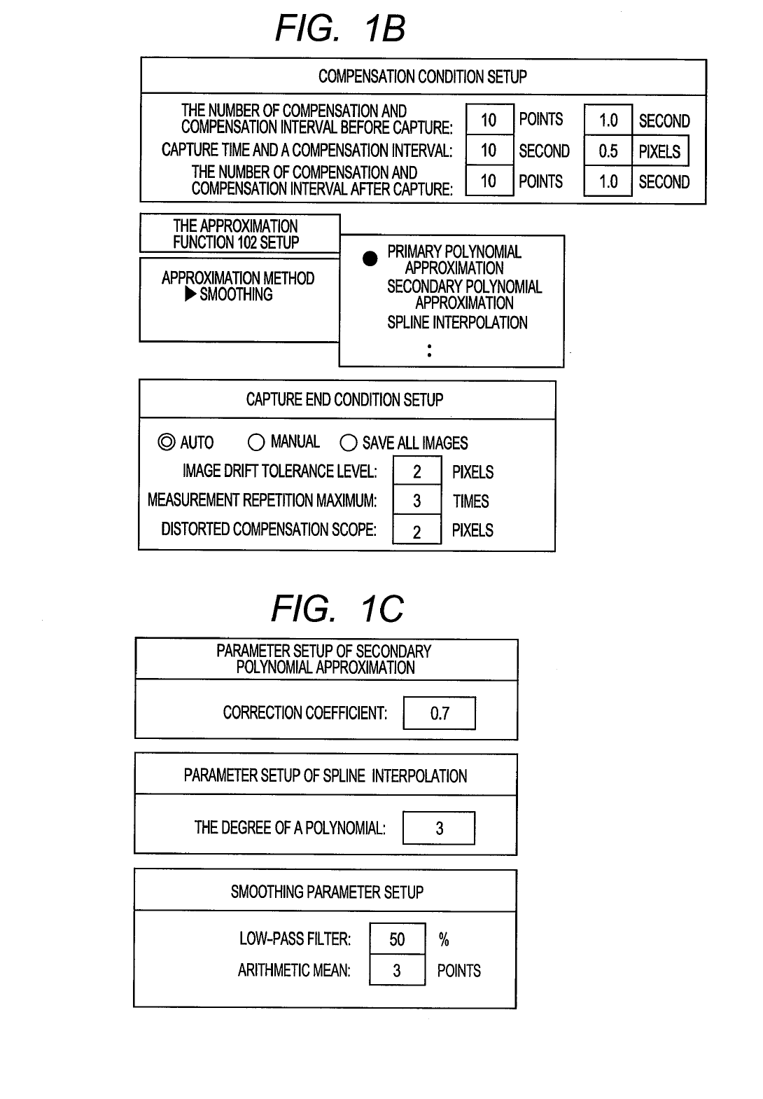

If the specimen is drifted under capturing a TEM image, the visual field captured by the electron detective camera 26 is gradually shifted. Therefore, an image that is blurred in the drift direction is stored. That is, the same phenomenon as captured by the fast scan method of STEM occurs (FIG. 2B). In order to compensate the influence of the sample drift, the capture time of the temporary image is divided into plural times, and plural short time integration images corresponding to the frame integration image in the second embodiment are stored. The short time integration images are integrated while compensating the visual field shift between images to create a final image. The flow of sample drift compensation is the same as the case where the frame integration image of FIG. 3 is substituted by the short time images. Therefore, it was possible to obtain an image in which image blurring or image distortion is significantly reduced. Further, as a result of measuring the size of a pattern formed on the surface of the specimen using the image created as described above, the result that an error of several nm caused by the image blurring or image distortion is reduced was obtained.

According to the embodiment, it is possible to provide a transmission electron microscope (TEM) that is not influenced or little influenced by the sample drift even though the visual field diameter is a high magnification of 250 nm×250 nm and a measurement method using the same.

### Sixth Embodiment

The first to fourth embodiments show an example in which an image for measuring the visual field shift and the temporary image are formed by the same electron beam. In contrast, in the SEM/STEM that forms an image by synchronizing the raster scanning signal of the incident electron beam with the detector signal, the image for measuring the sample drift and the temporary image may be formed by separate electron beams.

For example, the STEM image may be used as an image for measuring the visual field shift and an EDX image may be used as a temporary image. The STEM image may be used as an image for measuring the visual field shift and an EELS image may be used as a temporary image. A reflective electron beam image of the SEM may be used as an image for measuring the visual field shift and a secondary electron image may be used as a temporary image.

Further, multiple combinations may be considered. If a low image SN image is used as a temporary image, an image having higher SN than the low image SN image is preferably set as an image for measuring the drift. Further, if the second embodiment is applied to a combination in which the SN of the temporary image is low and the SN of the drift compensation image is high, a first frame integration image that is a temporary image and a locus of the visual field shift obtained from the image for measuring the visual field shift are stored, but the image for measuring the visual field shift may not be stored. Therefore, it is possible to reduce the memory required for processing. A target memory is created from the first frame integration image based on the approximate formula obtained from the locus of the visual field shift after completing the capture.

Further, in order to reduce the memory, a process of obtaining a final image from the first frame integration image and the locus of the visual field shift may be divided into plural times. If the number of sheets of first frame integration image is larger than the predetermined number, an approximation formula is calculated from the locus of the visual field shift obtained for the period of time to create and store a final image, and the first frame integration image is removed from the memory. This process is repeated to obtain plural temporary images. A high SN final image is created by integrating the plural temporary images while compensating the visual field shift.

Thereby, it was possible to obtain an image in which image blurring or image distortion is significantly reduced. Further, as a result of measuring the size of a pattern formed on the surface of the specimen using the image created as described above, the result that an error of several nm caused by the image blurring or image distortion is reduced was obtained.

Further, in the case of capturing an EELS image, if the image shift largely changes, the position of the electron beam that is incident onto the energy loss electron spectroscope 41 is shifted, and thus an absolute value of energy to be detected is varied. For solving the above problem, a function of automatically compensating the positional deviation of the electron beam incident onto the energy loss electron spectroscope 41 so as to match the control value of the image shift 16 using the alignment deflector 21 may be provided.

In addition, the movable range of the image shift is limited to a small area. If the image shift exceeds the movable range, a function of compensating the movement of the image shift using the specimen stage may be used. In a device including a piezo stage, the drift compensation may be carried out by using the piezo stage, not the image shift.

Furthermore, in the first to fifth embodiments, an example in which an electron beam is used as a charged particle beam incident onto the specimen is described. However, even when an image is formed by other charged particle beam such as a focused ion beam, the same drift compensation system may be used.

According to the embodiment, it is possible to provide a charged particle beam microscope is not influenced or little influenced by the sample drift even though the visual field diameter is a high magnification of 250 nm×250 nm, and a measurement method using the same. Further, by forming the image for measuring the sample drift and the temporary image using separate electron beams, a final image that is not influenced or little influenced by the sample drift even though the SN of the temporary image is very small can be obtained.

### INDUSTRIAL APPLICABILITY

By applying the present invention to a high resolution microscope such as an STEM, an SEM, or a TEM, it is possible to obtain the high precision of the sample drift compensation and improve TAT. If the compensation performance of the sample drift is improved, the image blurring or distortion is reduced and information obtained from the image is increased. The efficiency of measurement, inspection, and analysis of a nanodevice or a nanomaterial by an electron microscope is significantly improved, so that the development thereof is accelerated.

### REFERENCE SIGNS LIST

11 . . . electron gun
11′ . . . electron gun control circuit
12 . . . condenser lens
12′ . . . condenser lens control unit
13 . . . condenser aperture
13′ . . . condenser aperture control unit
14 . . . alignment deflector
14′ . . . alignment deflector control unit
15 . . . stigmator
15′ . . . stigmator control unit
16 . . . image shift deflector
16′ . . . image shift deflector control unit
17 . . . scanning deflector
17′ . . . scanning deflector control unit
18 . . . objective lens
18′ . . . objective lens control unit
19 . . . specimen stage
19′ . . . specimen stage control unit
20 . . . projective lens
20′ . . . projective lens control unit
21 . . . alignment deflector
21′ . . . alignment deflector control unit
22 . . . electron detector
22′ . . . electron detector control unit
23 . . . scattering angle select aperture
23′ . . . scattering angle select aperture control unit
24 . . . objective aperture
24′ . . . objective aperture control unit
25 . . . selected-area aperture
25′ . . . selected-area aperture control unit
26 . . . electron beam detective camera
26′ . . . electron beam detective camera control unit
28 . . . image formation unit
29 . . . computer with control program and image processing program
29-1 . . . record part
29-2 . . . calculation part
29-3 . . . analysis part that obtains an approximation function used for compensating a visual field shift caused by the sample drift from plural visual field shifts
29-4 . . . display unit that displays the locus of sample drift obtained from the plural visual field shifts or the locus of visual field shift and the approximation function of the visual field shift
30 . . . specimen
31 . . . primary electron beam
32-1 . . . low angle scatter electron
32-2 . . . high angle scatter electron
32-3 . . . secondary electron
32-4 . . . elastic scattered transmission electron beam
32-5 . . . nonelastic scattered transmission electron beam
33 . . . laser beam
34 . . . specimen height sensor using the laser beam 33
34′ . . . height sensor control unit
40 . . . energy dispersive x-ray spectroscope
40′ . . . energy dispersive x-ray spectroscope control unit
41 . . . energy loss electron spectroscope
41′ . . . energy loss electron spectroscope control unit
101 . . . approximation function obtained from a locus of sample drift before capture
102 . . . approximation function obtained from a locus of sample drift before and after capture
103 . . . approximation function obtained from a locus of sample drift under capture
200 . . . housing

1. A charged particle beam microscope, comprising:
a charged particle generating source;
a charged particle generating source control circuit that controls the charged particle generating source;
a specimen stage that mounts a specimen onto which the charged particle discharged from the charged particle generating source is irradiated;
a specimen stage control circuit that controls the specimen stage;
a detector that detects the charged particles from the specimen;
a detector control circuit that controls the detector;
a computer that controls the control circuits; and
a display part that is connected to the computer, wherein the computer includes:
a recording part that records a plurality of images created using charged particles from a predetermined pattern formed on the specimen at different timings;
a calculation part that calculates the visual field shift amount between the plurality of images using the predetermined pattern in the image; and
an analysis unit that calculates an approximation function that is used for the compensation of the visual field shift caused by the sample drift from the visual field shift amount.

2. The charged particle beam microscope according to claim 1, wherein the display part displays a locus of the sample drift obtained from the visual field shift amount between the plurality of images and the approximation function of the visual field shift.

3. The charged particle beam microscope according to claim 1, wherein the display part displays a locus of the visual field shift obtained from the visual field shift amount between the plurality of images and the approximation function of the visual field shift.

4. A method of measuring a predetermined pattern from an image obtained by irradiating a charged particle beam onto the predetermined pattern of a specimen using a charged particle beam microscope, the method comprising:
a first step of capturing a plurality of images including the predetermined pattern at different timings;
a second step of obtaining the visual field shift amount between the plurality of images;
a third step of obtaining an approximation function that is used for compensating the visual field shift caused by the sample drift from the visual field shift amount between the plurality of images; and
a fourth step of offsetting the visual field shift based on the approximation function.

5. The measuring method according to claim 4, wherein the third step includes:
a step of selecting an approximate function from a plurality of candidates.

6. A charged particle beam microscope, comprising: a charged particle generating source;
a charged particle generating source control circuit that controls the charged particle generating source;
a specimen stage that mounts a specimen onto which the charged particle discharged from the charged particle generating source is irradiated;
a specimen stage control circuit that controls the specimen stage;
a detector that detects the charged particles from the specimen;
a detector control circuit that controls the detector;
a computer that controls the control circuits; and
a display part that is connected to the computer,
wherein the display unit carries out:
a compensation condition setup that compensates a visual field shift in a captured image obtained based on the charged particles from the specimen;
an approximation function setup that approximates a locus of a sample drift of the specimen used for compensating the visual field shift; and
a capture completion condition setup of the specimen.

7. The charged particle beam microscope according to claim 6, wherein the compensation condition setup is set to at least one of:
the number of compensation and a compensation interval before capturing a temporary image of the specimen;
a capture time of the temporary image and a compensation interval of the temporary image of the specimen; and
the number of compensation and a compensation interval after capturing the temporary image of the specimen.

8. The charged particle beam microscope according to claim 6, wherein the approximation function setup is a setup of an approximation function obtained from a locus of the sample drift before capturing the temporary image of the specimen.

9. The charged particle beam microscope according to claim 8, wherein a compensation coefficient is set if the approximation function is a linear function and a degree is further set if the approximation function is a spline interpolation.

10. The charged particle beam microscope according to claim 9, wherein the approximation function setup is a setup of an approximation function obtained from a locus of the sample drift before and after capturing the temporary image of the specimen.

11. The charged particle beam microscope according to claim 10, wherein a compensation coefficient is set if the approximation function is a linear function and a degree is further set if the approximation function is a spline interpolation.

12. The charged particle beam microscope according to claim 6, wherein the capture completion condition setup is a setup for selecting whether to automatically determine or manually determine that the recapture is required.

13. The charged particle beam microscope according to claim 12, wherein if the setup is automatic, the setup of an available range of the visual field shift and the measurement repetition maximum is further performed.
